(19) United States
(12) Patent Application Publication
(10) Pub. No.: US 2016/0247700 A1
(43) Pub. Date: Aug. 25, 2016

(54) SUBSTRATE PRETREATMENT METHOD AND APPARATUS

(71) Applicant: Shenzhen China Star Optoelectronics Technology Co., Ltd., Shenzhen, Guangdong (CN)

(72) Inventors: Qinghua ZOU, Shenzhen, Guangdong (CN); Tsungyuan WU, Shenzhen, Guangdong (CN)

(73) Assignee: Shenzhen China Star Optoelectronics Technology Co., Ltd., Shenzhen, Guangdong (CN)

(21) Appl. No.: 14/426,971

(22) PCT Filed: Jul. 2, 2014
(86) PCT No.: PCT/CN2014/081439

§ 371 Date: Mar. 9, 2015

(30) Foreign Application Priority Data
Jun. 12, 2014 (CN) 201410261124.5

(51) Int. Cl. H01L 21/677; H01L 51/00; H01L 51/56

(52) U.S. Cl. CPC H01L 21/67745; H01L 51/56; H01L 51/0029

(57) ABSTRACT

The present invention provides a substrate pretreatment method and apparatus. The method includes the steps of: step 1, providing a substrate waiting for a pretreatment, an UV chamber and a loading chamber; step 2, providing a transfer chamber between the UV chamber and the loading chamber to connect the UV chamber and the loading chamber, providing a first sealing door at a place where the UV chamber and the transfer chamber are connected with each other, and providing a second sealing door at a place where the transfer chamber and the loading chamber are connected with each other; step 3, putting the substrate waiting for the pretreatment into the UV chamber; step 4, closing the UV chamber and sending dried oxygen into the UV chamber for performing an UV treatment; step 5, opening the first sealing door and transferring the substrate into the transfer chamber after the UV treatment being completed; step 6, closing the first sealing door, opening the second sealing door and transferring the substrate into the loading chamber after the substrate being completely transferred into the transfer chamber; step 7, closing the second sealing door and evacuating the loading chamber after the substrate being completely transferred into the loading chamber.

### FIELD OF THE INVENTION

The present invention relates to the field of manufacturing organic electroluminescent device, and more particularly to substrate pretreatment method and apparatus.

### BACKGROUND OF THE INVENTION

Organic electroluminescent device is a self-luminous device with advantages of low voltage, wide viewing angle, fast response and good temperature adaptability, and is a display technology of next generation. In view of the molecular weight of the material used in the organic electroluminescent device, the organic electroluminescent device can be divided into small molecular organic light-emitting device (OLED) and polymer light-emitting device (PLED). The manufacturing processes of the organic electroluminescent device are different due to different molecular weight. The OLED is mainly manufactured by thermal evaporation method while the PLED is manufactured by spin coating or ink jet printing method.

An OLED usually includes: a substrate, an ITO transparent anode disposed on the substrate, a hole injection layer (HIL) disposed on the ITO transparent anode, a hole transport layer (HTL) disposed on the hole injection layer, an emission layer (EML) disposed on the hole transport layer, an electron transport layer (ETL) disposed on the emission layer, an electron injection layer (EIL) disposed on the electron transport layer, and a cathode disposed on the electron injection layer. In order to improve efficiency, the emission layer is usually a guest-host doping system.

OLED devices are very sensitive to moisture and oxygen such that the degree of drying of the substrate is very critical. The moisture would damage the OLED device after the device being manufactured even only a very small amount of residual moisture on the substrate. The structure of the material is damaged and the optoelectronic property of organic material is impacted because of the electrochemical reaction occurred between the moisture and the organic material, especially when a current is conducted therein, such that the OLED device is deteriorated and life of the OLED device is reduced.

In the conventional pretreatment method for OLED substrate, the substrate (glass or plastic substrate) goes through cleaning, baking and UV treatment before entering the coating machine. Wherein, the UV treatment may improve surface work function of the ITO (indium tin oxide) to enhance hole injection capability, and may remove organic residues from ITO surface as well. However, since a same robot (machine apparatus automatically performs the work) is used for all the equipment of each of the stages in the pretreatment method, the substrate is transferred to the loading chamber of the organic coating machine by the robot after the substrate being processed with the UV treatment. Humidity inside the robot chamber is the same as the humidity of the outside clean room, which is generally 55%, because the robot chamber cannot be made hermetically sealed but just with an atmosphere having high cleanness. Accordingly, moisture re-adheres to surface of the substrate in the procedure. The moisture cannot be completely dried even though the conventional loading chamber is capable of heating. Besides, it takes a long time to dry the moisture such that the tact time (i.e., time from the first substrate being putted into (or outputted from) the pipeline to the second substrate being putted into (or outputted from) the pipeline on the production line) is extended.

### SUMMARY OF THE INVENTION

An object of the present invention is to provide a substrate pretreatment method to prevent the substrate from passing through normal air such that moisture adhering can be avoided, baking time in the loading chamber can be saved, tact time can be reduced, and performance and life of the OLED device are improved.

Another object of the present invention is to provide a substrate pretreatment apparatus having easy structure and being easily operated to optimize substrate pretreatment process.

To achieve the above mentioned object, the present invention provides a substrate pretreatment method, including the steps of:

Step 1, providing a substrate waiting for a pretreatment, an UV chamber and a loading chamber;

Step 2, providing a transfer chamber between the UV chamber and the loading chamber to connect the UV chamber and the loading chamber, providing a first sealing door at a place where the UV chamber and the transfer chamber are connected with each other, and providing a second sealing door at a place where the transfer chamber and the loading chamber are connected with each other;

Step 3, putting the substrate waiting for the pretreatment into the UV chamber;

Step 4, closing the UV chamber and sending dried oxygen into the UV chamber for performing an UV treatment;

Step 5, opening the first sealing door and transferring the substrate into the transfer chamber after the UV treatment being completed;

Step 6, closing the first sealing door, opening the second sealing door and transferring the substrate into the loading chamber after the substrate being completely transferred into the transfer chamber; and

Step 7, closing the second sealing door and evacuating the loading chamber after the substrate being completely transferred into the loading chamber.

The loading chamber is evacuated until a degree of vacuum is below E-4 pa in Step 7.

The transfer chamber is a hermetically sealed chamber after the first sealing door and the second sealing door being closed.

A drive apparatus is set in the transfer room for transferring the substrate.

The drive apparatus is a drive roller.

An entrance door is set on a side of the UV chamber away from the transfer chamber, and an exit door is set on a side of the loading chamber away from the transfer chamber to connect with a coating machine.

The substrate is an OLED substrate, and the pretreatment is a coating pretreatment.

The present invention further provides a substrate pretreatment apparatus, including an UV chamber, a transfer chamber and a loading chamber, wherein the transfer chamber is provided between the UV chamber and the loading chamber, a first sealing door is provided at a place where the UV chamber and the transfer chamber are connected with each other, a second sealing door is provided at a place where the transfer chamber and the loading chamber are connected with each other, and the transfer chamber is a hermetically sealed chamber after the first sealing door and the second sealing door being closed.

A drive apparatus is set in the transfer room for transferring a substrate, and the drive apparatus is a drive roller.

An entrance door is set on a side of the UV chamber away from the transfer chamber, an exit door is set on a side of the loading chamber away from the transfer chamber to connect with a coating machine, the substrate is an OLED substrate, and the pretreatment is a coating pretreatment.

The present invention further provides a substrate pretreatment apparatus, including an UV chamber, a transfer chamber and a loading chamber, wherein the transfer chamber is provided between the UV chamber and the loading chamber, a first sealing door is provided at a place where the UV chamber and the transfer chamber are connected with each other, a second sealing door is provided at a place where the transfer chamber and the loading chamber are connected with each other, and the transfer chamber is a hermetically sealed chamber after the first sealing door and the second sealing door being closed;

wherein a drive apparatus is set in the transfer room for transferring a substrate, and the drive apparatus is a drive roller;

wherein an entrance door is set on a side of the UV chamber away from the transfer chamber, an exit door is set on a side of the loading chamber away from the transfer chamber to connect with a coating machine, the substrate is an OLED substrate, and the pretreatment is a coating pretreatment.

The beneficial effect of the present invention is: the substrate pretreatment method and substrate pretreatment apparatus provided by the present invention utilizes a hermetically sealed transfer chamber to connect the UV chamber and the loading chamber such that the substrate enters the loading chamber via the hermetically sealed transfer chamber but not the normal air. Accordingly, the substrate is prevented from moisture adhering after the UV treatment being completed so that baking time in the loading chamber can be saved, tact time can be reduced, and performance and life of the OLED device are improved. The substrate pretreatment apparatus has easy structure and is easily operated so that substrate pretreatment process can be optimized.

Please refer to the detailed description and the attached drawings for further understanding the feature and technique content of the present invention. The attached drawings are only for providing reference and explanation but not for limiting the present invention.

### BRIEF DESCRIPTION OF THE DRAWINGS

The technique contents and other beneficial effects of the present invention will become more readily apparent to those ordinarily skilled in the art through detailed description with accompanying drawings.

FIG. 1 is a flow chart of a substrate pretreatment method of the present invention.

FIG. 2 is a perspective view of a substrate pretreatment apparatus of the present invention.

FIG. 3 is a top view of the substrate pretreatment apparatus of the present invention.

### DETAILED DESCRIPTION OF PREFERRED EMBODIMENTS

In order to more specifically describe the technical means and the effects of the present invention, the best embodiments and drawings are described in detail as follows.

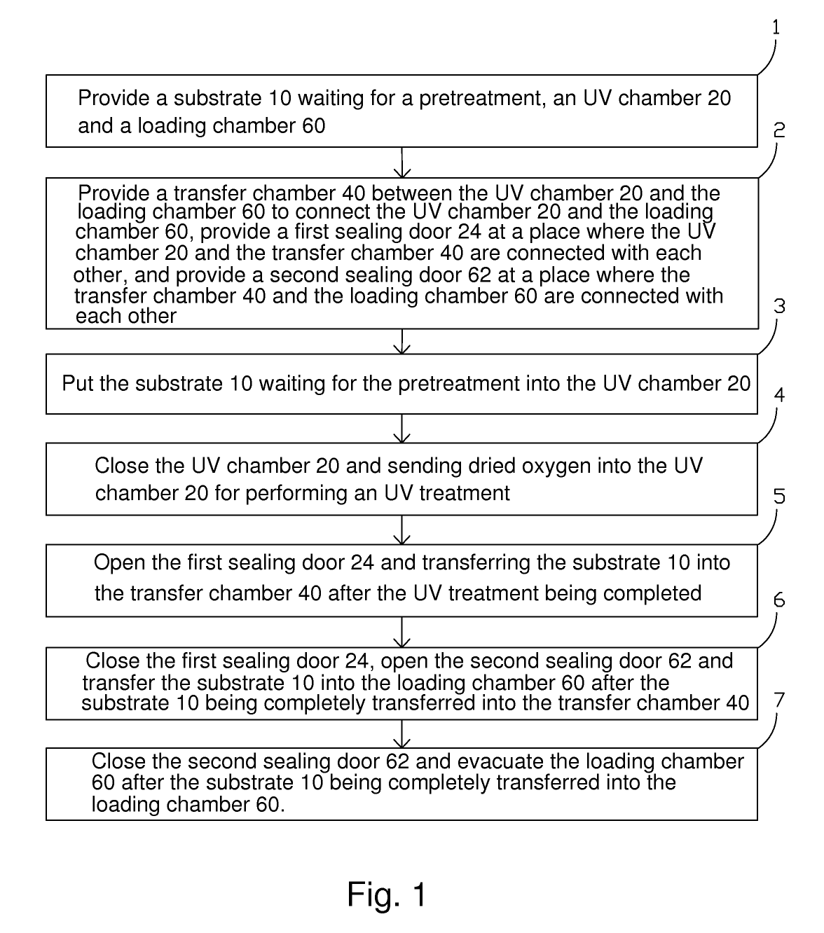

Please refer to FIGS. 1-3. The present invention provides a substrate pretreatment method, which includes the steps as follows:

Step 1: Provide a substrate 10 waiting for a pretreatment, an UV chamber 20 and a loading chamber 60.

The substrate 10 is an OLED substrate, and the pretreatment is the coating pretreatment.

Step 2: Provide a transfer chamber 40 between the UV chamber 20 and the loading chamber 60 to connect the UV chamber 20 and the loading chamber 60, provide a first sealing door 24 at a place where the UV chamber 20 and the transfer chamber 40 are connected with each other, and provide a second sealing door 62 at a place where the transfer chamber 40 and the loading chamber 60 are connected with each other, wherein the transfer chamber 40 is a hermetically sealed chamber after the first sealing door 24 and the second sealing door 62 being closed.

A drive apparatus 42 is set in the transfer room 40 for transferring the substrate 10, and the drive apparatus 42 is a drive roller.

Step 3: Put the substrate 10 waiting for the pretreatment into the UV chamber 20.

Step 4: Close the UV chamber 20 and sending dried oxygen into the UV chamber 20 for performing an UV treatment.

Step 5: Open the first sealing door 24 and transferring the substrate 10 into the transfer chamber 40 after the UV treatment being completed.

Step 6: Close the first sealing door 24, open the second sealing door 62 and transfer the substrate 10 into the loading chamber 60 after the substrate 10 being completely transferred into the transfer chamber 40.

Step 7: Close the second sealing door 62 and evacuate the loading chamber 60 after the substrate 10 being completely transferred into the loading chamber 60. The substrate 10 is transferred into a coating machine (not shown) until the degree of vacuum of the loading chamber 60 is below E-4 pa.

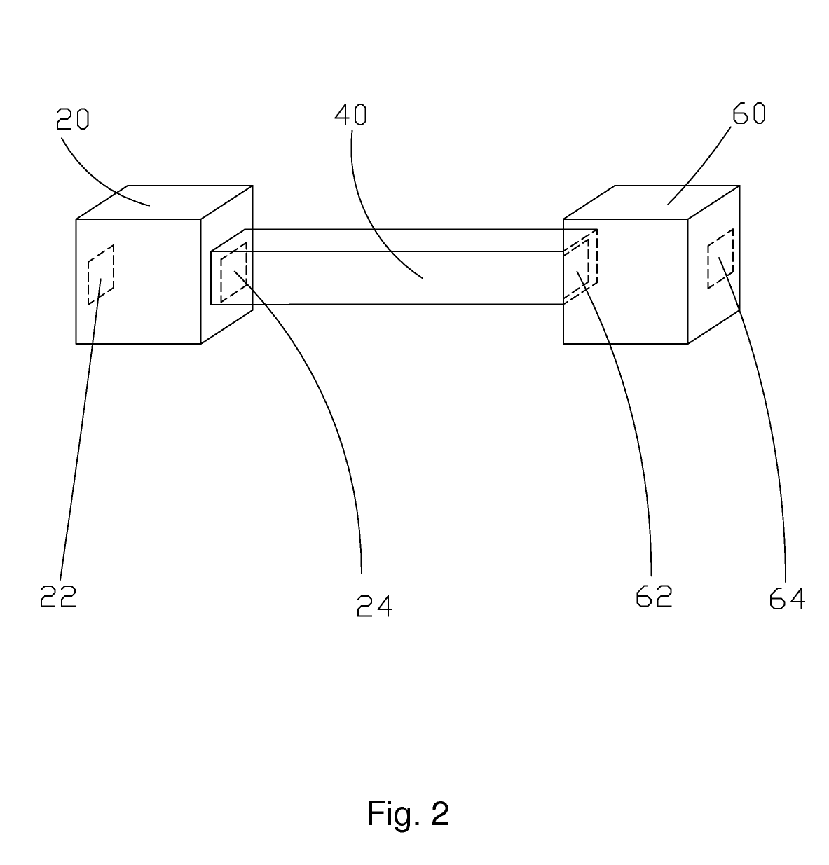

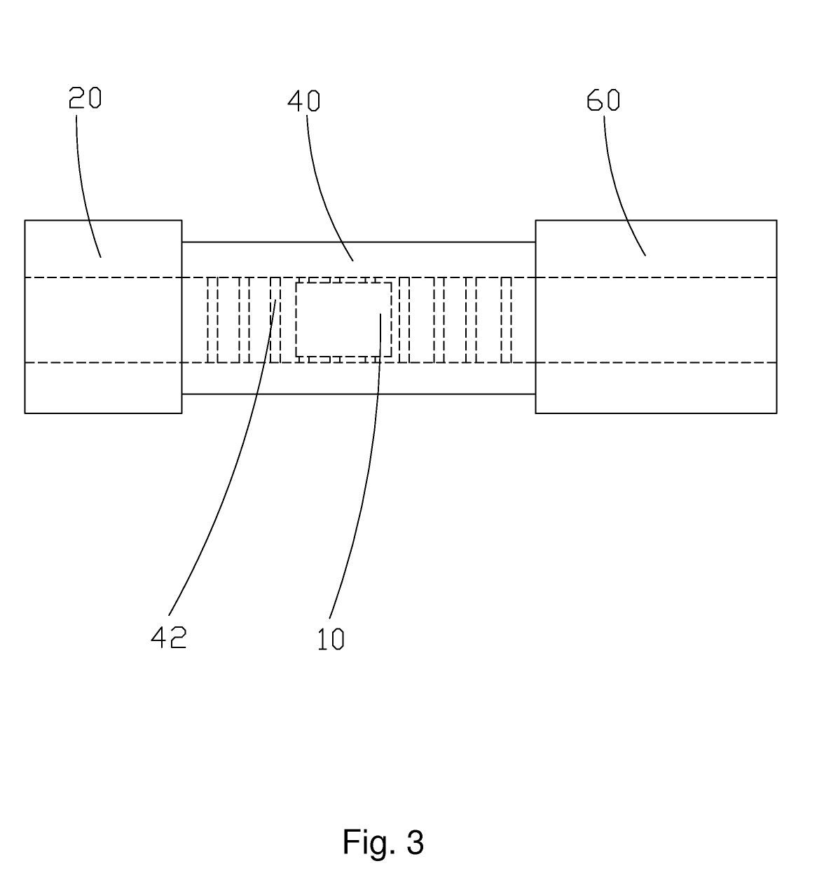

An entrance door 22 is set on a side of the UV chamber 20 away from the transfer chamber 40, and an exit door 64 is set on a side of the loading chamber 60 away from the transfer chamber 40 to connect with the coating machine (not shown). Please refer to FIGS. 2-3. The present invention provides a substrate pretreatment apparatus for performing coating pretreatment on the substrate 10. The substrate pretreatment apparatus includes the UV chamber 20, the transfer chamber 40 and the loading chamber 60, wherein the transfer chamber 40 is provided between the UV chamber 20 and the loading chamber 60, a first sealing door 24 is provided at a place where the UV chamber 20 and the transfer chamber 40 are connected with each other, a second sealing door 62 is provided at a place where the transfer chamber 40 and the loading chamber 60 are connected with each other, and the transfer chamber 40 is a hermetically sealed chamber after the first sealing door 24 and the second sealing door 62 being closed.

The substrate 10 is an OLED substrate.

The drive apparatus 42 is set in the transfer room 40 for transferring the substrate 10, and the drive apparatus 42 is a drive roller.

The entrance door 22 is set on a side of the UV chamber 20 away from the transfer chamber 40, and the exit door 64 is set on a side of the loading chamber 60 away from the transfer chamber 40 to connect with the coating machine (not shown).

When the substrate pretreatment takes place, the substrate 10 waiting for the pretreatment is put into the UV chamber 20; the UV chamber 20 is closed and dried oxygen is sent into the UV chamber 20 for performing an UV treatment; the first sealing door 24 is opened and the substrate 10 is transferred into transfer chamber 40 by the drive apparatus 42 after the UV treatment being completed; the first sealing door 24 is closed and the second sealing door 62 is opened after the substrate 10 being completely transferred into the transfer chamber to transfer the substrate 10 into the loading chamber 60; the second sealing door 62 is closed and the loading chamber 60 is evacuated after the substrate 10 being completely transferred into the loading chamber 60; the substrate 10 is transferred into the coating machine (not shown) until the degree of vacuum of the loading chamber 60 is below E-4 pa.

In summary, the substrate pretreatment method and substrate pretreatment apparatus provided by the present invention utilizes a hermetically sealed transfer chamber to connect the UV chamber and the loading chamber such that the substrate enters the loading chamber via the hermetically sealed transfer chamber but not the normal air. Accordingly, the substrate is prevented from moisture adhering after the UV treatment being completed so that baking time in the loading chamber can be saved, tact time can be reduced, and performance and life of the OLED device are improved. The substrate pretreatment apparatus has easy structure and is easily operated so that substrate pretreatment process can be optimized.

Those with ordinary skill in the art are capable of make various modifications and arrangements in accordance to the technical solutions and technical ideas of the present invention, and those modifications and arrangements should be covered by the scope of the appended claims of the present invention.

What is claimed is:

1. A substrate pretreatment method, comprising the steps of:
Step 1, providing a substrate waiting for a pretreatment, an UV chamber and a loading chamber;
Step 2, providing a transfer chamber between the UV chamber and the loading chamber to connect the UV chamber and the loading chamber, providing a first sealing door at a place where the UV chamber and the transfer chamber are connected with each other, and providing a second sealing door at a place where the transfer chamber and the loading chamber are connected with each other;
Step 3, putting the substrate waiting for the pretreatment into the UV chamber;
Step 4, closing the UV chamber and sending dried oxygen into the UV chamber for performing an UV treatment;
Step 5, opening the first sealing door and transferring the substrate into the transfer chamber after the UV treatment being completed;
Step 6, closing the first sealing door, opening the second sealing door and transferring the substrate into the loading chamber after the substrate being completely transferred into the transfer chamber; and
Step 7, closing the second sealing door and evacuating the loading chamber after the substrate being completely transferred into the loading chamber.

2. The substrate pretreatment method of claim 1, wherein the loading chamber is evacuated until a degree of vacuum is below E-4 pa in Step 7.

3. The substrate pretreatment method of claim 1, wherein the transfer chamber is a hermetically sealed chamber after the first sealing door and the second sealing door being closed.

4. The substrate pretreatment method of claim 1, wherein a drive apparatus is set in the transfer room for transferring the substrate.

5. The substrate pretreatment method of claim 4, wherein the drive apparatus is a drive roller.

6. The substrate pretreatment method of claim 1, wherein an entrance door is set on a side of the UV chamber away from the transfer chamber, and an exit door is set on a side of the loading chamber away from the transfer chamber to connect with a coating machine.

7. The substrate pretreatment method of claim 1, wherein the substrate is an OLED substrate, and the pretreatment is a coating pretreatment.

8. A substrate pretreatment apparatus, including an UV chamber, a transfer chamber and a loading chamber, wherein the transfer chamber is provided between the UV chamber and the loading chamber, a first sealing door is provided at a place where the UV chamber and the transfer chamber are connected with each other, a second sealing door is provided at a place where the transfer chamber and the loading chamber are connected with each other, and the transfer chamber is a hermetically sealed chamber after the first sealing door and the second sealing door being closed.

9. The substrate pretreatment apparatus of claim 8, wherein a drive apparatus is set in the transfer room for transferring a substrate, and the drive apparatus is a drive roller.

10. The substrate pretreatment apparatus of claim 8, wherein an entrance door is set on a side of the UV chamber away from the transfer chamber, an exit door is set on a side of the loading chamber away from the transfer chamber to connect with a coating machine, the substrate is an OLED substrate, and the pretreatment is a coating pretreatment.

11. A substrate pretreatment apparatus, including an UV chamber, a transfer chamber and a loading chamber, wherein the transfer chamber is provided between the UV chamber and the loading chamber, a first sealing door is provided at a place where the UV chamber and the transfer chamber are connected with each other, a second sealing door is provided at a place where the transfer chamber and the loading chamber are connected with each other, and the transfer chamber is a hermetically sealed chamber after the first sealing door and the second sealing door being closed;
wherein a drive apparatus is set in the transfer room for transferring a substrate, and the drive apparatus is a drive roller;
wherein an entrance door is set on a side of the UV chamber away from the transfer chamber, an exit door is set on a side of the loading chamber away from the transfer chamber to connect with a coating machine, the substrate is an OLED substrate, and the pretreatment is a coating pretreatment.
